(19) United States
(12) Patent Application Publication
(10) Pub. No.: US 2018/0053648 A1
(43) Pub. Date: Feb. 22, 2018

(54) METHOD OF MANUFACTURING SEMICONDUCTOR DEVICE

(71) Applicant: Sumitomo Electric Industries, Ltd., Osaka-shi (JP)

(72) Inventors: Ken Nakata, Yokohama-shi (JP); Keiichi Yui, Yokohama-shi (JP); Hiroyuki Ichikawa, Yokohama-shi (JP); Isao Makabe, Yokohama-shi (JP); Tsuyoshi Kouchi, Yokohama-shi (JP)

(21) Appl. No.: 15/783,760

(22) Filed: Oct. 13, 2017

Related U.S. Application Data
(62) Division of application No. 14/285,181, filed on May 22, 2014.

(30) Foreign Application Priority Data
May 23, 2013 (JP) 2013-109069

(51) Int. Cl. H01L 21/02; H01L 29/778; H01L 29/20

(52) U.S. Cl. CPC H01L 21/0262; H01L 29/7786; H01L 21/0254; H01L 29/2003; H01L 21/02494; H01L 21/02458; H01L 21/02378

(57) ABSTRACT

A method of manufacturing a semiconductor device according to an embodiment of the present invention includes steps of forming an AlN layer on a SiC substrate under conditions of a growth temperature of 1100° C. or lower, growth pressure of 100 torr or less and a V/III ratio of source gasses of 500 or less, forming a channel layer made of a nitride semiconductor, forming an electron supply layer, and forming gate, source, and drain electrodes.

### CROSS-REFERENCE TO RELATED APPLICATIONS

This application is a Divisional of U.S. patent application Ser. No. 14/285,181, filed May 22, 2014, which claims the benefit of Japanese Patent Application No. 2013-109069, filed May 23, 2013.

### BACKGROUND OF THE INVENTION

### Field of the Invention

The present invention relates to a semiconductor device and a method of manufacturing the same, and, for example, to a semiconductor device in which a nitride semiconductor is provided on a semi-insulating SiC substrate, and a method of manufacturing the same.

### Related Background Art

A semiconductor device using a nitride semiconductor, e.g., an FET (Field Effect Transistor) such as an HEMT (High Electron Mobility Transistor), is used for an amplification element which operates at a high frequency and a high output, such as an amplifier for a mobile-phone base station. An example of the semiconductor device includes a structure in which a base layer of aluminum nitride (AlN), a channel layer of gallium nitride (GaN), and an electron supply layer of aluminum gallium nitride (AlGaN) are sequentially stacked on a semi-insulating silicon carbide (SiC) substrate (e.g., see Japanese Patent Application Laid-Open Publication No. 2006-286741).

### SUMMARY OF THE INVENTION

In the above-described structure, an effect of suppression of a current change at the time of blocking of a high frequency signal can be expected when a film thickness of the AlN layer is appropriately designed. However, a current change rate after the high frequency signal is blocked changes with the film thickness of the AlN layer, as illustrated in FIG. 2 in Japanese Patent Application Laid-Open Publication No. 2006-286741. Accordingly, a high frequency amplification characteristic of the semiconductor device is made unstable.

The present invention has been made in view of the aforementioned problem, and an object of the present invention is to stabilize a current recovery rate after a high frequency signal is blocked.

A semiconductor device according to one aspect of the present invention includes a SiC substrate; an AlN layer provided on the SiC substrate and having a maximum valley depth of 5 nm or less; a channel layer provided on the AlN layer and composed of a nitride semiconductor; an electron supply layer provided on the channel layer and having a greater band gap than the channel layer; and a gate electrode, a source electrode and a drain electrode provided on the electron supply layer. In the semiconductor device according to the aspect of the present invention, it is possible to stabilize a current recovery rate after a high frequency signal is blocked.

A method of manufacturing a semiconductor device according to one aspect of the present invention includes steps of forming an AlN layer on a SiC substrate in growth conditions in which a growth temperature is 1100° C. or less, growth pressure is 100 torr or less, and a V/III ratio of a source gas is 500 or less using an MOCVD method;

forming a channel layer composed of a nitride semiconductor on the AlN layer; forming, on the channel layer, an electron supply layer having a greater band gap than the channel layer; and forming a gate electrode, a source electrode and a drain electrode on the electron supply layer. In the method of manufacturing a semiconductor device according to the aspect of the present invention, it is possible to stabilize a current recovery rate after a high frequency signal is blocked.

According to the present invention, it is possible to stabilize the current recovery rate after the high frequency signal is blocked.

### BRIEF DESCRIPTION OF THE DRAWINGS

FIG. 1A illustrates a result of a measurement of a current change of a normal HEMT after a high frequency signal is blocked.

FIG. 1B illustrates a result of a measurement of a current change of an abnormal HEMT after a high frequency signal is blocked.

FIG. 2 is a cross-sectional SEM image of a structure in which an AlN layer and a GaN layer are stacked on a SiC substrate.

FIG. 3A is a diagram illustrating an energy band in an area of the AlN layer having a great film thickness.

FIG. 3B is a diagram illustrating an energy band in an area of the AlN layer having a small film thickness.

FIG. 4 is a cross-sectional view of a semiconductor device according to Example 1.

FIG. 5 is a diagram illustrating a relationship between a maximum valley depth Rv in an upper surface of the AlN layer and recovery time of a current after a high frequency signal is blocked.

FIG. 6 is a diagram illustrating a relationship between a growth temperature of the AlN layer and a V/III ratio of a source gas, and a maximum valley depth Rv in an upper surface of the AlN layer.

FIG. 7 is a diagram illustrating a relationship between growth pressure of the AlN layer and the maximum valley depth Rv in an upper surface of the AlN layer.

FIG. 8 is a diagram illustrating a relationship between introduction time of NH₃ relative to introduction time of TMA and the maximum valley depth Rv in an upper surface of the AlN layer.

FIG. 9 is a cross-sectional SEM image showing a shape of the AlN layer formed on the SiC substrate in a semiconductor device according to Example 2.

### DESCRIPTION OF THE PREFERRED EMBODIMENTS

### Description of Embodiments of the Present Invention

First, content of embodiments of the present invention will be listed and described. A semiconductor device according to one embodiment of the present invention includes a SiC substrate, an AlN layer provided on the SiC substrate and having a maximum valley depth of 5 nm or less, a channel layer provided on the AlN layer and composed of a nitride semiconductor, an electron supply layer provided on the channel layer and having a greater band gap than the channel layer, and a gate electrode, a source electrode and a drain electrode provided on the electron supply layer. In the semiconductor device according to the embodiment of the present invention, it is possible to stabilize a current recovery rate after a high frequency signal is blocked.

Further, in the semiconductor device according to the embodiment, the maximum valley depth may be depth from a base line to the deepest valley, in which the base line is an average line of a surface profile of the AlN layer.

Further, in the semiconductor device according to the embodiment, an average film thickness of the AlN layer may be 5 nm or more and 40 nm or less.

Further, in the semiconductor device according to the embodiment, the channel layer may include GaN.

Further, in the semiconductor device according to the embodiment, the electron supply layer may include AlGaN or an InAlN.

Further, in the semiconductor device according to the embodiment, the AlN layer may be provided in contact with (0001) Si face of the SiC substrate.

A method of manufacturing a semiconductor device according to one embodiment of the present invention includes steps of: forming an AlN layer on a SiC substrate in growth conditions in which a growth temperature is 1100° C. or less, growth pressure is 100 torr or less, and a V/III ratio of a source gas is 500 or less using an MOCVD method; forming a channel layer composed of a nitride semiconductor on the AlN layer; forming, on the channel layer, an electron supply layer having a greater band gap than the channel layer; and forming a gate electrode, a source electrode and a drain electrode on the electron supply layer. The V/III ratio of a source gas means a ratio of supply molar quantity of a group V source gas to supply molar quantity of a group III source gas. In the method of manufacturing a semiconductor device according to the embodiment of the present invention, it is possible to stabilize a current recovery rate after a high frequency signal is blocked.

In the method of manufacturing a semiconductor device according to the embodiment, a group III source gas and a group V source gas included in the source gas may be introduced into a growth chamber at the same time, the group V source gas may be introduced after the group III source gas is introduced, or the group III source gas may be introduced within 30 seconds after the group V source gas is introduced.

In the method of manufacturing a semiconductor device according to the embodiment, the group III source gas included in the source gas may be trimethyl aluminum or triethyl aluminum, and the group V source gas may be ammonia.

In the method of manufacturing a semiconductor device according to the embodiment, the AlN layer may be formed in contact with (0001) Si face of the SiC substrate.

In the method of manufacturing a semiconductor device according to the embodiment, the AlN layer may have a maximum valley depth of 5 nm or less.

In the method of manufacturing a semiconductor device according to the embodiment, an average film thickness of the AlN layer may be 5 nm or more and 40 nm or less.

In the method of manufacturing a semiconductor device according to the embodiment, wherein the maximum valley depth may be depth from a base line to the deepest valley, the base line being an average line of a surface profile of the AlN layer.

### Details of an Embodiment of the Present Invention

Next, an embodiment of the present invention will be described in detail with reference to the drawings.

First, an experiment conducted by the inventors will be described. The inventors prepared a plurality of HEMTs in which an AlN layer having a film thickness of 20 nm, a GaN layer having a film thickness of 1.0 μm, and an AlGaN layer having a film thickness of 25 nm were sequentially stacked on a semi-insulating SiC substrate, and a gate electrode, a source electrode and a drain electrode were provided on the AlGaN layer. Also, a current change after a high frequency signal of the plurality of prepared HEMTs was blocked was measured. As a result, in some of the HEMTs, a recovery rate in a current recovery process after the high frequency signal was blocked was found to be lower than that of normal HEMTs.

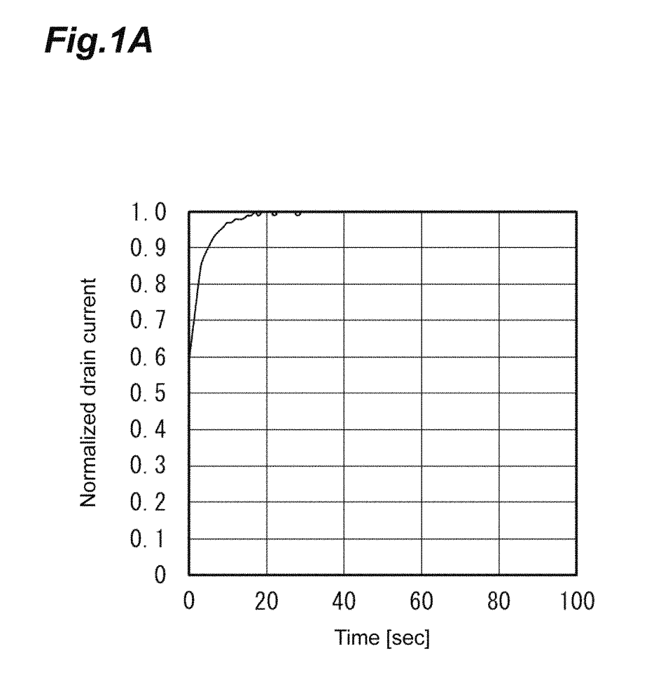

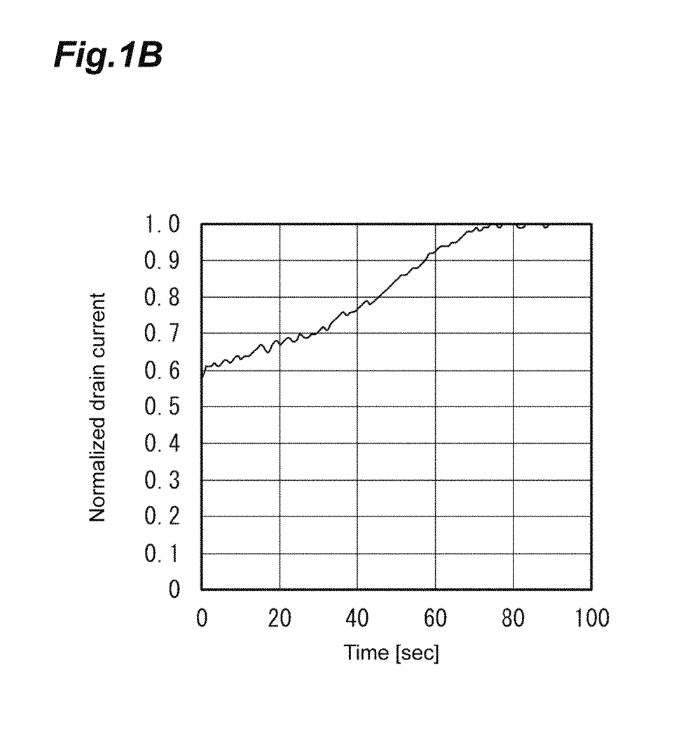

FIG. 1A illustrates a result of a measurement of a current change of a normal HEMT after a high frequency signal is blocked, and FIG. 1B illustrates a result of a measurement of a current change of an abnormal HEMT after a high frequency signal is blocked. A horizontal axis of FIGS. 1A and 1B indicates time, and a vertical axis indicates a normalized drain current obtained by normalizing a drain current after high frequency output is blocked with a drain current before a high frequency operation. In addition, a result of a measurement when a drain voltage is 50 V is illustrated in FIGS. 1A and 1B. In the normal HEMT, the drain current reduced to 0.6 (i.e., 0.6 times) of an initial value (a drain current value immediately before the high frequency signal is blocked) immediately after the high frequency signal is blocked recovers to the initial value in about 20 seconds, as illustrated in FIG. 1A. On the other hand, in some abnormal HEMTs, even when 30 seconds has passed, the drain current only recovers to about 0.7 of the initial value (i.e., about 0.7 times the initial value), and it takes about 70 seconds for the drain current to recover to the initial value, as illustrated in FIG. 1B.

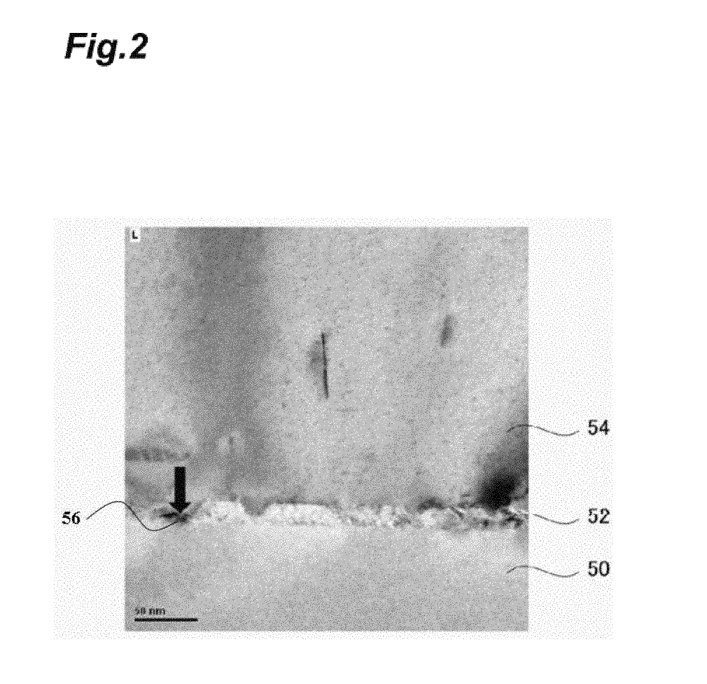

The current recovery rates after the high frequency signal is blocked are considered to be different among a plurality of HEMTs for the following reasons. FIG. 2 is a cross-sectional SEM (Scanning Electron Microscope) image of a structure in which an AlN layer and a GaN layer are stacked on a SiC substrate. An AlN layer 52 and a GaN layer 54 are sequentially formed on a semi-insulating SiC substrate 50, as illustrated in FIG. 2. An average film thickness of the AlN layer 52 is 20 nm. The AlN layer 52 is not flat under general growth conditions, and has an island-shaped pattern having a plurality of valleys. A deepest valley 56 of the plurality of valleys is indicated by an arrow in FIG. 2. Such an island-shaped pattern is obtained because a growth mode of AlN becomes an S-K mode (Stranski-Krastanov Growth Mode) due to a difference in a lattice constant between SiC and AlN. Therefore, the AlN layer 52 on the SiC substrate 50 includes both areas having a great film thickness and areas having a small film thickness.

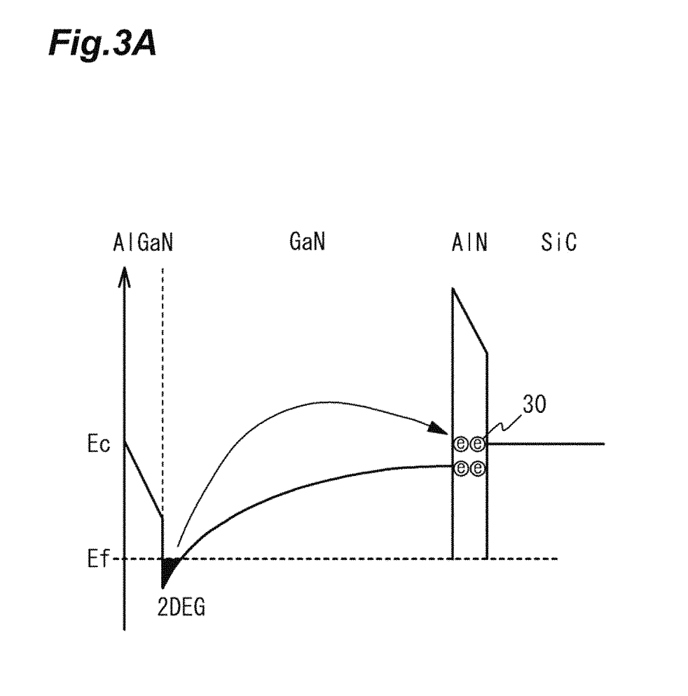

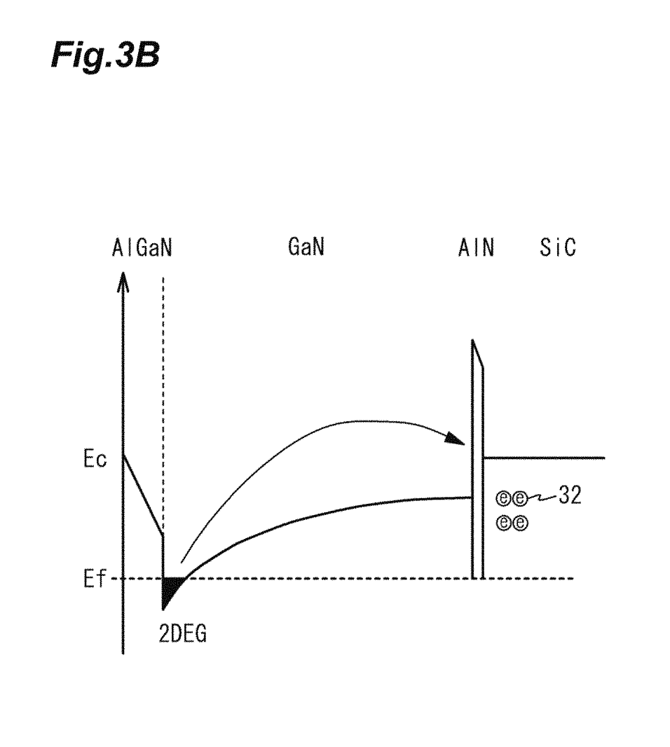

Next, an energy band of the HEMT in which an AlN layer, a GaN layer and an AlGaN layer are sequentially stacked on a semi-insulating SiC substrate will be described. FIG. 3A is a diagram illustrating an energy band in an area of the AlN layer having a great film thickness, and FIG. 3B is a diagram illustrating an energy band in an area of the AlN layer having a small film thickness. There are electron traps 30 which capture electrons of a two-dimensional electron gas (2DEG) in the AlN layer in the area having a thick film thickness, as illustrated in FIG. 3A. Accordingly, the electrons of the 2DEG are captured by the electron traps 30 and thus a current change at the time of blocking of the high frequency signal occurs. The electron traps 30 are formed due to a transition defect caused by the difference in lattice constant between the SiC substrate and the AlN layer, and the number of the electron traps 30 increases as the AlN layer is thicker. Therefore, in the areas of the AlN layer having a great film thickness, most electrons of the 2DEG are captured by the AlN layer.

On the other hand, in the areas of the AlN layer having a small film thickness, the electrons of the 2DEG pass through the AlN layer and arrive at the SiC substrate, as illustrated in FIG. 3B. The semi-insulating SiC substrate has high resistance due to doping of a transition metal or the like, and electron traps 32 are formed due to the transition metal or the like. Therefore, the electrons which have arrived at the SiC substrate are captured by the electron traps 32. A current change at the time of blocking of a high frequency signal occurs also due to the electrons of the 2DEG being captured by the electron traps 32.

Thus, most electrons of the 2DEG are captured by the AlN layer in the areas of the AlN layer having a great film thickness, and by the SiC substrate in the areas of the AlN layer having a small film thickness. A rate of the current recovery in a current recovery process after a high frequency signal is blocked is different according to whether the electrons of the 2DEG are captured by the AlN layer or by the SiC substrate. Since the island-shaped pattern of the AlN layer formed on the SiC substrate is different among a plurality of HEMTs, a difference in recovery rate in the current recovery process after a high frequency signal is blocked among the plurality of HEMTs is considered to be caused due to a mechanism described in FIGS. 3A and 3B. Here, “among a plurality of HEMTs” refers to, for example, “among respective HEMTs” in a plurality of HEMTs formed in one wafer.

Therefore, an embodiment in which flatness of the AlN layer formed on the SiC substrate can be improved and the recovery rate in the current recovery process after a high frequency signal is blocked can be stabilized will be described below.

### First Embodiment

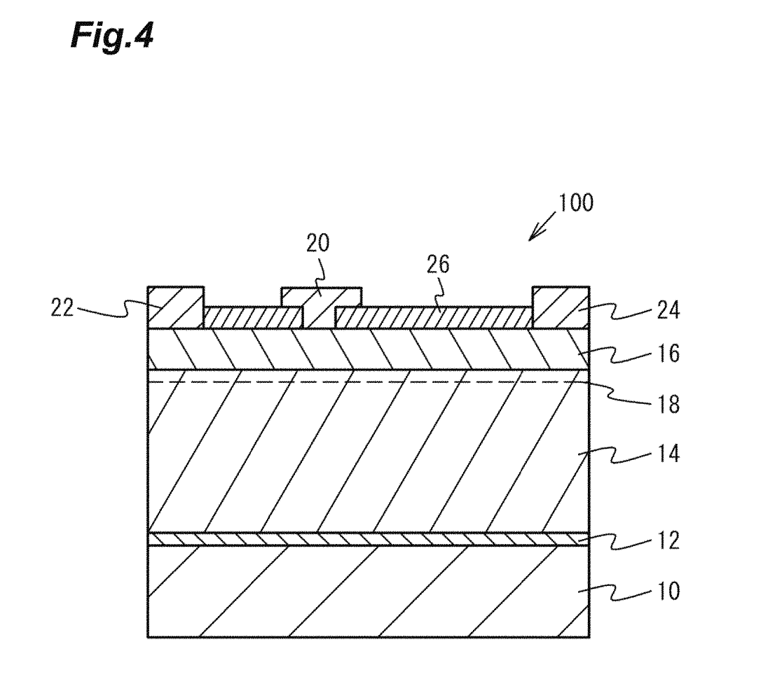

FIG. 4 is a cross-sectional view of a semiconductor device according to a first embodiment. The semiconductor device of the first embodiment is an HEMT. In the semiconductor device 100 of the first embodiment, an AlN layer 12 is provided on a semi-insulating SiC substrate 10, as illustrated in FIG. 4. The SiC substrate 10 has, for example, a hexagonal crystal structure such as 4H or 6H. The AlN layer 12 is provided in contact with a main surface of the SiC substrate 10, e.g., a (0001) Si face of the SiC substrate 10. The semi-insulating SiC substrate 10 is used because a loss in a high frequency operation is suppressed.

A channel layer 14 is composed of, for example, a GaN layer is provided on the AlN layer 12. The channel layer 14 is provided, for example, in contact with an upper surface of the AlN layer 12. An electron supply layer 16 is provided on the channel layer 14. The electron supply layer 16 has a greater band gap than the channel layer 14. In other words, when the channel layer 14 is composed of the GaN layer, the electron supply layer 16 has a greater band gap than GaN. The electron supply layer 16 is composed of, for example, an AlGaN layer. As the electron supply layer 16, for example, an InAlN layer may be used in addition to the AlGaN layer. The electron supply layer 16 is provided, for example, in contact with an upper surface of the channel layer 14. A two-dimensional electron gas (2DEG) 18 is formed on the side of the channel layer 14 of an interface between the channel layer 14 and the electron supply layer 16.

A gate electrode 20, and a source electrode 22 and a drain electrode 24 between which the gate electrode 20 is interposed are provided on the electron supply layer 16. The gate electrode 20 is, for example, a multilayered metal film in which a Ni layer and a Au layer are stacked sequentially from the SiC substrate 10 side. Each of the source electrode 22 and the drain electrode 24 is, for example, a multi-layer metal film in which a Ti layer and an Al layer are stacked sequentially from the SiC substrate 10 side. A protective film 26 composed of, for example, a SiN film is provided on the electron supply layer 16 in an area other than an area in which the gate electrode 20, the source electrode 22 and the drain electrode 24 are provided.

The upper surface of the AlN layer 12 has reduced irregularities, and a maximum valley depth Rv in the upper surface is 5 nm or less. Conventionally, the maximum valley depth Rv in the upper surface of the AlN layer 12 is, for example, about 20 nm. In addition, the maximum valley depth conforms to JIS B0601-2001, and refers to a maximum value of a depth to the deepest valley, when viewed from a base line, when an average line of surface roughness (i.e., a surface shape) is used as the base line. Namely, the maximum valley depth is depth from a base line to the deepest valley, when the base line is an average line of a surface profile of the AlN layer. In addition, Rv is a value measured using an atomic force microscope as a surface roughness meter. It will be described herein to make the maximum valley depth Rv in the upper surface of the AlN layer 12 to be 5 nm or less. The maximum valley depth Rv in the upper surface of the AlN layer 12 may be changed depending on a growth condition of the AlN layer 12, as will be described in detail below. Therefore, in the structure of FIG. 4, a plurality of semiconductor devices in which the maximum valley depth Rv in the upper surface of the AlN layer 12 having an average film thickness of 20 nm was different and other details were the same were prepared and a current change after a high frequency signal was blocked was measured.

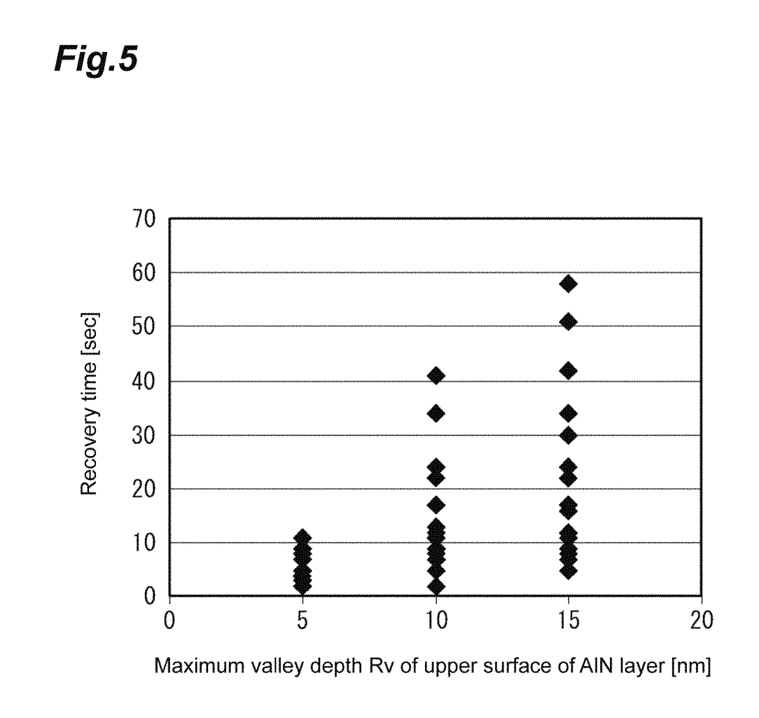

FIG. 5 is a diagram illustrating a relationship between the maximum valley depth Rv in the upper surface of the AlN layer 12 and recovery time of current after a high frequency signal is blocked. A horizontal axis of FIG. 5 indicates the maximum valley depth Rv of the upper surface of the AlN layer 12, and a vertical axis is recovery time until a normalized drain current obtained by normalizing a drain current after a high frequency output is blocked with a drain current before a high frequency operation becomes 0.9. It can be seen that a variation of the recovery time of the current after a high frequency signal is blocked is great when the maximum valley depth Rv of the upper surface of the AlN layer 12 is 10 nm and 15 nm, whereas the variation of the recovery time is suppressed to be small when the maximum valley depth Rv is 5 nm or less, as illustrated in FIG. 5.

Based on the foregoing, in the semiconductor device 100 according to the first embodiment, the maximum valley depth Rv in the upper surface of the AlN layer 12 provided on the SiC substrate 10 is 5 nm or less. Accordingly, it is possible to stabilize a current recovery rate after the high frequency signal is blocked, as illustrated in FIG. 5.

In view of further stabilization of the current recovery rate after the high frequency signal is blocked, the maximum valley depth Rv in the upper surface of the AlN layer 12 is more preferably 4 nm or less, and further preferably 3 nm or less.

An average film thickness of the AlN layer 12 is preferably 5 nm or more, more preferably 10 nm or more, and further preferably 15 nm or more in view of causing the AlN layer 12 to function as a buffer layer. In addition, the average film thickness of the AlN layer 12 is preferably 40 nm or less, more preferably 25 nm or less, and further preferably 20 nm or less in view of a current change at the time of blocking of a high frequency signal being able to be suppressed by making the AlN layer 12 thin, as described in Japanese Patent Application Laid-Open Publication No. 2006-286741.

When the channel layer 14 is a GaN layer and a film thickness of the channel layer 14 is smaller than 0.5 μm, mobility of the electrons becomes small due to crystal distortion. Therefore, the film thickness of the channel layer 14 is preferably 0.5 μm or more, more preferably 0.75 μm or more, and further preferably 1.0 μm or more. In addition, when the film thickness of the channel layer 14 is greater than 2.0 μm, cracking may occur. Therefore, the film thickness of the channel layer 14 is preferably 2.0 μm or less, more preferably 1.5 μm or less, and further preferably 1.0 μm or less.

In the semiconductor device 100 according to the first embodiment, while a cap layer is not provided on the electron supply layer 16 as illustrated in FIG. 4, the cap layer may be provided on the electron supply layer 16. For example, a GaN layer may be used as the cap layer in this case.

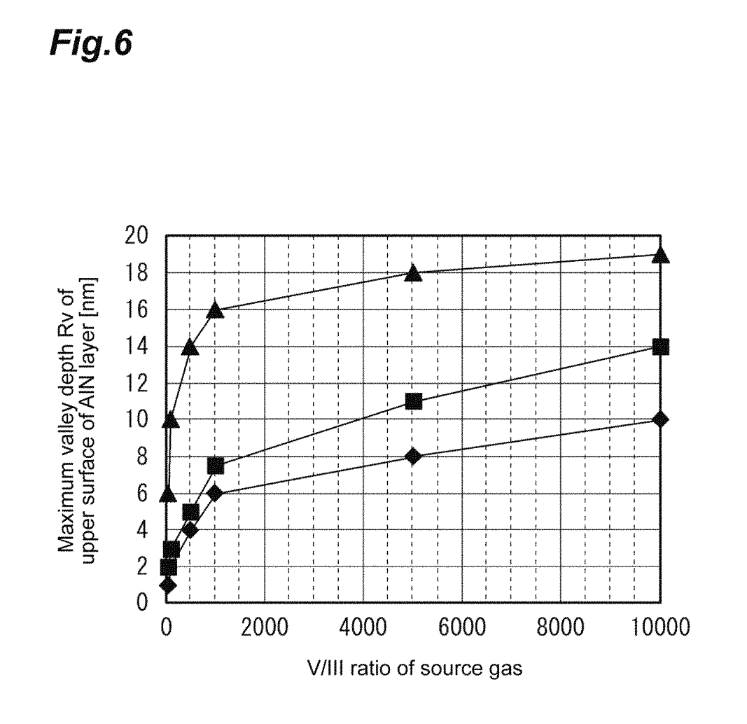

Next, a relationship between a growth condition of the AlN layer and a maximum valley depth Rv in the upper surface of the AlN layer when the AlN layer is formed on the SiC substrate using a MOCVD (Metal Organic Chemical Vapor Deposition) method will be described. First, the maximum valley depths Rv in the upper surfaces of the AlN layers were evaluated when the AlN layers having an average film thickness of 20 nm were formed on the SiC substrates by maintaining the growth pressure at 50 torr and changing the growth temperature and the V/III ratio of the source gases using the MOCVD method. Trimethyl aluminum (TMA) and ammonia (NH₃) were used as the source gases. FIG. 6 is a diagram illustrating a relationship between the growth temperature of the AlN layer and the V/III ratio of the source gases, and the maximum valley depth Rv in the upper surface of the AlN layer. A horizontal axis of FIG. 6 indicates the V/III ratio of the source gases, and a vertical axis indicates the maximum valley depth Rv of the upper surface of the AlN layer. A plot of a lozenge mark in FIG. 6 indicates a case in which the growth temperature of the AlN layer is 1050° C., a plot of a square mark indicates a case in which the growth temperature of the AlN layer is 1100° C., and a plot of a triangular mark indicates a case in which the growth temperature of the AlN layer is 1150° C. It can be seen that the maximum valley depth Rv of the upper surface of the AlN layer can be 5 nm or less when the growth temperature of the AlN layer is 1100° C. or less and the V/III ratio of the source gases is 500 or less, as illustrated in FIG. 6.

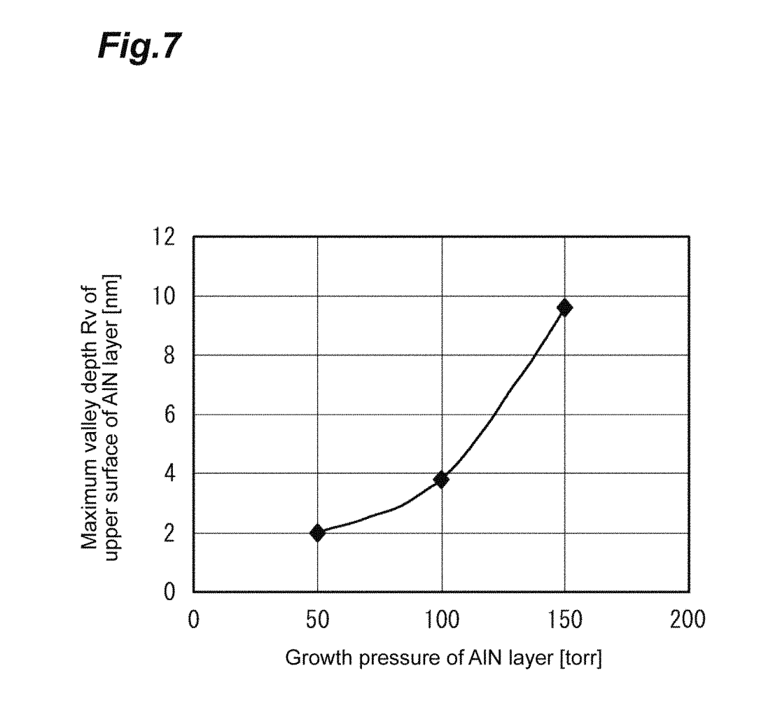

Then, the maximum valley depths Rv in the upper surfaces of the AlN layers were evaluated when the AlN layers having an average film thickness of 20 nm were formed on the SiC substrate by maintaining the growth temperature at 1050° C. and the V/III ratio of the source gases at 500 and changing the growth pressure using the MOCVD method. FIG. 7 is a diagram illustrating a relationship between the growth pressure of the AlN layer and the maximum valley depth Rv in the upper surface of the AlN layer. A horizontal axis of FIG. 7 indicates the growth pressure, and a vertical axis indicates the maximum valley depth Rv of the upper surface of the AlN layer. It can be seen that the maximum valley depth Rv of the upper surface of the AlN layer can be 5 nm or less when the growth pressure of the AlN layer is 100 torr or less, as illustrated in FIG. 7.

Based on the foregoing, in the semiconductor device 100 of the first embodiment, when the AlN layer 12 is formed on the SiC substrate 10 under conditions in which the growth temperature is 1100° C. or less, the growth pressure is 100 torr or less, and the V/III ratio of the source gases is 500 or less using the MOCVD method, the maximum valley depth Rv in the upper surface of the AlN layer 12 can be 5 nm or less. Accordingly, it is possible to stabilize a current recovery rate after the high frequency signal is blocked.

Preferable growth conditions of the AlN layer when the AlN layer 12 is formed using the MOCVD method are as follows in view of further reducing the maximum valley depth Rv in the upper surface of the AlN layer 12. Namely, the growth temperature of the AlN layer 12 is preferably 1050° C. or less, and more preferably 100020 C. or less. The growth pressure is preferably 75 torr or less and more preferably 50 torr or less. The V/III ratio of the source gases is preferably 400 or less, and more preferably 300 or less. In addition, a typical lower limit of the growth temperature may be 900° C., a typical lower limit of the growth pressure when the AlN layer 12 is formed using the MOCVD method may be 36 torr, and a typical lower limit of the V/III ratio of the source gases may be 10.

### Second Embodiment

Next, a method of manufacturing a semiconductor device according to a second embodiment will be described. Since a semiconductor device obtained using the method of manufacturing a semiconductor device according to the second embodiment has the same configuration as the semiconductor device 100 of the first embodiment illustrated in FIG. 4, a description of the semiconductor device obtained using the method of manufacturing a semiconductor device according to the second embodiment is omitted. In the method of manufacturing a semiconductor device according to the second embodiment, first, a semi-insulating SiC substrate 10 cleaned by RCA cleaning is introduced into a growth chamber of an MOCVD apparatus. Then, an upper surface of the SiC substrate 10 is cleaned for three minutes at 1100° C. under a hydrogen atmosphere before the AlN layer 12 is grown on the SiC substrate 10.

Subsequently, the AlN layer 12 is grown on the SiC substrate 10 under the following conditions using an MOCVD method. Trimethyl aluminum and ammonia which are source gases used for growth of the AlN layer 12 are introduced into the growth chamber of the MOCVD apparatus at the same time.

Source gases: Trimethyl aluminum (TMA) and ammonia (NH₃)

Growth temperature: 1050° C.

Growth pressure: 50 torr

V/III ratio: 100

Average film thickness: 20 nm

The reason for which the source gases TMA and NH₃ are introduced into the growth chamber simultaneously will be described here. Usually, when a gas introduced into the growth chamber changes, a temperature of the substrate varies due to a change of heat conduction, and thus NH₃ is introduced prior to introduction of TMA. However, if NH₃ is introduced in advance, the upper surface of the SiC substrate 10 may be nitrided and partially coated with SiN. When the upper surface of the SiC substrate 10 is partially coated with SiN, unevenness is generated in growth of the AlN layer 12 formed on the SiC substrate 10, and irregularities are easily formed in the upper surface of the AlN layer 12.

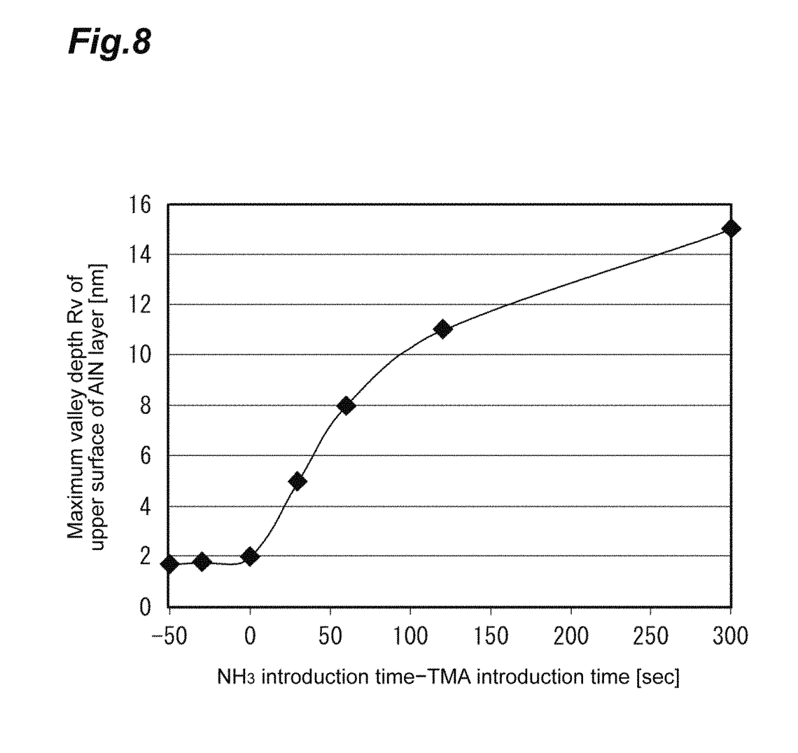

FIG. 8 is a diagram illustrating a relationship between introduction time of NH₃ relative to introduction time of TMA and a maximum valley depth Rv in the upper surface of the AlN layer 12. A horizontal axis of FIG. 8 indicates a value obtained by subtracting the introduction time of the TMA from the introduction time of NH₃ (NH₃ introduction time—TMA introduction time). Namely, when (NH₃ introduction time—TMA introduction time) is 0, TMA and NH₃ are introduced into the growth chamber of the MOCVD apparatus at the same time. When (NH₃ introduction time—TMA introduction time) is a negative value, TMA is introduced into the growth chamber first. When (NH₃ introduction time—TMA introduction time) is a positive value, NH₃ is introduced into the growth chamber first. A vertical axis of FIG. 8 indicates a maximum valley depth Rv of the upper surface of the AlN layer 12. It is seen that the maximum valley depth Rv of the upper surface of the AlN layer 12 is 5 nm or less when TMA is introduced within 30 seconds after introducing NH₃, NH₃ and TMA are introduced at the same time, or TMA is introduced earlier than NH₃, as illustrated in FIG. 8. Therefore, in the method of manufacturing a semiconductor device according to the second embodiment, TMA and NH₃ are introduced into the growth chamber of the MOCVD apparatus at the same time.

Then, the channel layer 14 including a GaN layer is grown on the AlN layer 12 under the following conditions using, for example, an

MOCVD method.

Source gases: Trimethyl gallium (TMG), NH₃

Growth temperature: 1080° C.

Growth pressure: 100 torr

Film thickness: 1 μm

Then, the electron supply layer 16 composed of an AlGaN layer is grown on the channel layer 14 under the following conditions using, for example, the MOCVD method.

Source gases: TMA, TMG and NH₃

Growth temperature: 1080° C.

Growth pressure: 100 torr

Film thickness: 25 nm

Al composition ratio: 20%

Then, the protective film 26 having a film thickness of 100 nm and composed of a SiN film is formed on the electron supply layer 16 using, for example, a plasma CVD method. In addition, an n-type GaN layer may be interposed between the electron supply layer 16 and the protective film 26. Then, the gate electrode 20 composed of a Ni layer and a Au layer stacked from the SiC substrate 10 side is formed on the electron supply layer 16 using, for example, an evaporation method and a liftoff method. The source electrode 22 and the drain electrode 24, which are ohmic electrodes composed of a Ti layer and an Al layer stacked from the SiC substrate 10 side, are formed on both sides of the gate electrode 20 using, for example, an evaporation method and a liftoff method. A gate length is, for example, 0.9 μm, a distance between the source and the gate is, for example, 1.5 μm, and a distance between the gate and the drain is, for example, 8 μm.

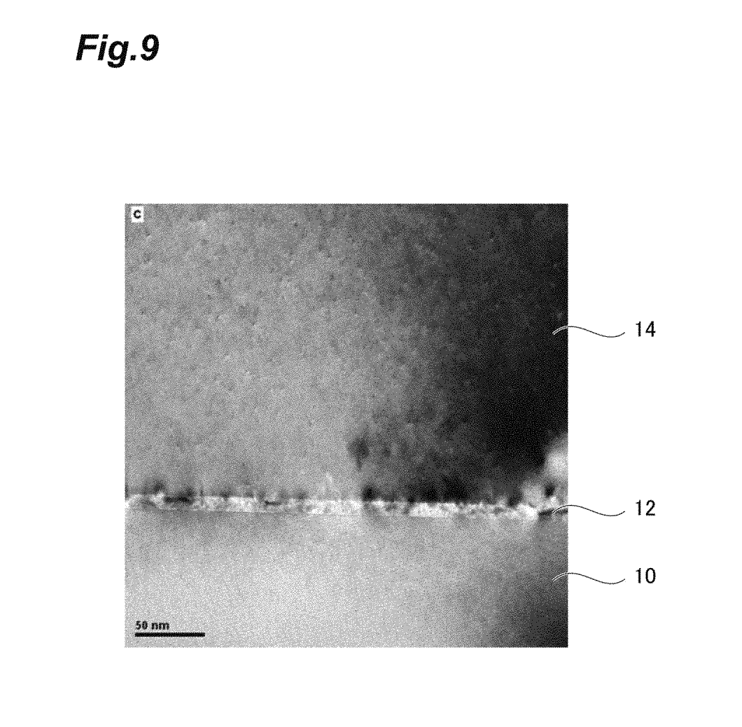

FIG. 9 is a cross-sectional SEM image of a semiconductor device prepared using the method of manufacturing a semiconductor device according to the second embodiment. The irregularities of the upper surface of the AlN layer 12 formed on the SiC substrate 10 decrease and the maximum valley depth Rv in the upper surface of the AlN layer 12 is 5 nm or less, as illustrated in FIG. 9. Thus, the maximum valley depth Rv in the upper surface of the AlN layer 12 is equal to or less than 5 nm because the AlN layer 12 is grown under conditions of a growth temperature of 1050° C. (1100° C. or less), growth pressure of 50 torr (100 torr or less), and a V/III ratio of the source gases of 100 (500 or less).

A leak current at the time of pinch-off was measured for the semiconductor device of the example prepared using the method of manufacturing a semiconductor device according to the second embodiment. The leak current at the time of pinch-off is defined as a drain current per unit gate width when a drain voltage is 50 V and a gate voltage is (threshold voltage—0.5 V). As a result, the leak current at the time of pinch-off was 2×10⁻⁶ A/mm

Further, semiconductor devices of a plurality of examples prepared using the method of manufacturing a semiconductor device according to the second embodiment were prepared and a current change at the time of blocking of a high frequency signal was measured for each semiconductor device. For measurement of the current change, the semiconductor device was operated for one minute with a saturated output under conditions in which the drain voltage was 50 V, and then the current change at the time of blocking of a high frequency signal was measured. As a result, in all of the semiconductor devices of the plurality of examples, a normalized drain current obtained by normalizing a drain current after blocking a high frequency output with a drain current before a high frequency operation was about 0.6 immediately after the high frequency signal was blocked, and then time required for the normalized drain current to recover to 0.9 was within ten and several seconds.

Next, a semiconductor device of Comparative example 1 will be described. A method of manufacturing a semiconductor device in Comparative example 1 is different from the method of manufacturing a semiconductor device according to the second embodiment in that a process of cleaning the upper surface of the SiC substrate 10 before the AlN layer 12 is grown is not performed, and that the growth conditions when the AlN layer 12 is grown on the SiC substrate 10 using the MOCVD method were changed into the following conditions. In other words, as an order of introducing TMA and NH₃ which are source gases used for growth of the AlN layer 12 into the growth chamber, TMA was introduced about five minutes after introduction of NH₃. In addition, the growth conditions were changed into the following growth conditions.

Source gases: TMA, NH₃

Growth temperature: 1100° C.

Pressure: 50 torr

V/III ratio: 5000

Average film thickness: 20 nm

Manufacture of subsequent layers after the AlN layer 12 was performed using the same method as the manufacturing method according to the second embodiment. For the semiconductor device of Comparative example 1, a leak current at the time of pinch-off was measured using the same method as the example manufactured using the method of manufacturing a semiconductor device according to the second embodiment. As a result, the leak current at the time of pinch-off of Comparative example 1 was 2×10⁻⁶ A/mm, and the leak current at the time of pinch-off of Comparative example 1 and the leak current at the time of pinch-off of the example manufactured using the method of manufacturing a semiconductor device according to the second embodiment had the same level.

Further, a plurality of semiconductor devices of Comparative example 1 described above were prepared, and a current change at the time of blocking of a high frequency signal was measured for each semiconductor device using the same method as in the example manufactured using the method of manufacturing a semiconductor device according to the second embodiment. As a result, in all of the plurality of semiconductor devices of Comparative example 1, the normalized drain current immediately after the high frequency signal was blocked was about 0.6, which was the same level as in the example manufactured using the method of manufacturing a semiconductor device according to the second embodiment. However, in a plurality of Comparative examples 1, time required for the normalized drain current to return to 0.9 was longer in some of the semiconductor devices. In other words, there were the semiconductor devices in which a current recovery rate after the high frequency signal was blocked was low among the semiconductor devices of Comparative examples 1, as described with reference to FIGS. 1A and 1B.

As in the method of manufacturing a semiconductor device according to the second embodiment, the AlN layer 12 is formed at growth temperature of 1050° C. (1100° C. or less), pressure of 50 torr (100 torr or less) and a V/III ratio of the source gases of 100 (500 or less) using the MOCVD method, such that the maximum valley depth Rv in the upper surface of the AlN layer 12 can be 5 nm or less. As a result, it is possible to stabilize the current recovery rate after a high frequency signal is blocked.

As illustrated in FIG. 8, it is preferable that TMA (III group source gas) and NH₃ (V group source gas) be introduced into the growth chamber of the MOCVD apparatus at the same time, NH₃ be introduced into the growth chamber after TMA is introduced, or TMA be introduced into the growth chamber within 30 seconds after NH₃ is introduced when forming the AlN layer 12 so that the maximum valley depth Rv in the upper surface of the AlN layer 12 is 5 nm or less.

While a case in which the channel layer 14 is composed of the GaN layer has been described by way of example in the first and second embodiments, the channel layer 14 may be composed of another nitride semiconductor layer. The nitride semiconductor refers to GaN, InN, AlN, AlGaN, InGaN, InAlN, InAlGaN or the like. For the electron supply layer 16, a nitride semiconductor having a greater band gap than the channel layer 14 may be used. For example, when the channel layer 14 is composed of a GaN layer, the electron supply layer 16 may be an AlGaN layer or an InAlN layer. In addition, the source gases when the AlN layer 12 is grown using the MOCVD method are not limited to TMA and NH₃, and other group III and V source gases may be used as the source gases.

While the embodiments and the examples of the present invention have been described above in detail, the present invention is not limited to such specific embodiments and examples, and various variations and changes may be made without departing from the gist of the present invention defined in claims.

1-5. (canceled)

6. A method of manufacturing a semiconductor device, comprising:
forming an AlN layer on a SiC substrate in growth conditions in which a growth temperature is 1100° C. or less, growth pressure is 100 torr or less, and a V/III ratio of a source gas is 500 or less using an MOCVD method;
forming a channel layer composed of a nitride semiconductor on the AlN layer;
forming, on the channel layer, an electron supply layer having a greater band gap than the channel layer; and
forming a gate electrode, a source electrode and a drain electrode on the electron supply layer.

7. The method of manufacturing a semiconductor device according to claim 6, wherein a group III source gas and a group V source gas included in the source gas are introduced into a growth chamber at the same time, the group V source gas is introduced after the group III source gas is introduced, or the group III source gas is introduced within 30 seconds after the group V source gas is introduced.

8. The method of manufacturing a semiconductor device according to claim 6, wherein a group III source gas included in the source gas is trimethyl aluminum or triethyl aluminum, and a group V source gas is ammonia.

9-13. (canceled)
